(19) United States
(12) Patent Application Publication
(10) Pub. No.: US 2026/0114089 A1
(43) Pub. Date: Apr. 23, 2026

(54) LIGHT-EMITTING APPARATUS AND METHOD OF MANUFACTURING LIGHT-EMITTING APPARATUS

(71) Applicant: STANLEY ELECTRIC CO., LTD., Tokyo (JP)

(72) Inventors: Ryo YANAGISAWA, Tokyo (JP); Chizu SAITO, Tokyo (JP); Masao ARATANI, Tokyo (JP)

(73) Assignee: STANLEY ELECTRIC CO., LTD., Tokyo (JP)

(21) Appl. No.: 19/358,438

(22) Filed: Oct. 15, 2025

(30) Foreign Application Priority Data
Oct. 18, 2024 (JP) 2024-184233

(51) Int. Cl. H10H 20/85; H10H 20/01

(52) U.S. Cl. CPC H10H 20/8506; H10H 20/036; H10H 20/8508

(57) ABSTRACT

A light-emitting apparatus includes a light-transmitting member that covers a space on a package substrate in which a light-emitting element is disposed and transmits light. An upper surface of the package substrate is airtightly bonded with the light-transmitting member by a bonding layer made of glass. The upper surface of the package substrate has a first bonding layer with a frame shape of predetermined width surrounding a peripheral region with the light-emitting element is disposed, a groove surrounding outside of the first bonding layer, and a second bonding layer with a frame shape having a predetermined width surrounding outside of the groove. The bonding layer is interposed between the first bonding layer and a lower surface of the light-transmitting member and a region interposed between the second bonding layer and the lower surface of the light-transmitting member.

### CROSS-REFERENCE TO RELATED APPLICATION

This application claims the benefit of and priority to Japanese Patent Application No. 2024-184233 filed on Oct. 18, 2024, and the content thereof is incorporated herein by reference in its entirety.

### BACKGROUND OF THE INVENTION

### 1. Field of the Invention

The present invention relates to a light-emitting apparatus in which a light-emitting element is airtightly sealed.

### 2. Description of Related Art

In order to airtightly seal a light-emitting element or an electronic component, a package is known in which the light-emitting element or the electronic component is mounted on a substrate and covered with a lid member, and peripheries of the substrate and the lid member are airtightly sealed by brazing materials or the like.

For example, PTL 1 discloses a structure in which a semiconductor chip is mounted on a package body, and peripheries of a lid member and the package body are sealed with solder. Groove-like depressions are provided on a substrate of a sealing portion, solder balls are placed inside the depressions, and the lid member is bonded while filling the depressions with solder by melting the solder balls.

PTL 2 discloses a structure in which a crystal oscillator is mounted on a substrate and is covered with a lid member, and peripheries of the lid member and the substrate are sealed with glass. At this time, grooves are provided in a periphery of the substrate, glass flows into the grooves, and fillets are formed in a periphery of the glass, whereby an anchor effect occurs in the glass in the grooves.

PTL 3 discloses a structure in which a metalized layer that is a gold electrode is formed on an upper surface of a ceramic substrate, and the upper surface of the ceramic substrate and a lid member are sealed with a glass-sealing material attached to a periphery of a lower surface of the lid member. A groove is provided in a periphery of the substrate and a ceramic layer is placed on an upper surface of the metalized layer on inner walls and peripheries of the grooves in order to enable bonding with the glass-sealing material. The glass-sealing material is melted at a low temperature of 380° C. to 420° C. and insides of the grooves are filled with the glass-sealing material, and thus bonding strength in the horizontal direction is large.

PTL 4 discloses a structure in which a periphery of a substrate on which a piezoelectric vibrator is mounted and a periphery of a lid member are sealed using glass or a eutectic alloy having a low melting point. In sealing portions of the substrate and the lid member, grooves are formed to face each other, and the facing grooves are filled with the glass or the eutectic alloy having the low melting point.

### CITATION LIST

### Patent Literature

PTL 1: JP2021-150348A

PTL 2: JP2013-98594A

PTL 3: JPH01-171036U

PTL 4: JP2001-9374A

### SUMMARY OF THE INVENTION

As in the technique disclosed in PTL 1, when the solder is used as a bonding material with which the substrate and the lid member are sealed, it is necessary to form the metalized layer in a bonding portion, which causes complication of a manufacturing process.

On the other hand, as in PTLs 2 to 4, when the glass is used as the bonding material with which the substrate and the lid member are sealed, the metalized layer is not necessary. However, when the glass is melted to be formed thinly and also in a desired shape, bubbles are easily contained and it is not easy to form an airtight sealing portion.

Specifically, in order to form a glass bonding portion, the bonding portion can be formed in a printing process and a heating process by using a glass paste that contains glass frit. Accordingly, the processes are simplified. However, the bonding portion formed by heating the glass frit is particularly likely to contain bubbles between particles of the glass frit. When bubbles are continuous, airtightness cannot be maintained.

In the structures disclosed in PTLs 2 to 4, the grooves are completely filled with the glass to achieve an improvement in the bonding strength by the anchor effect of the glass filling the grooves. However, bubbles that are easily contained in the glass are not considered. When the grooves are completely filled with the glass, the bubbles cannot escape, and thus it is difficult to reduce the bubbles contained in the glass. When an amount of the glass is excessively large, the bonding portion protrudes inside and outside of the sealing portion, which causes defects.

An object of the invention is to provide a light-emitting apparatus in which a light-emitting element is sealed simply and airtightly while using a glass material such as glass frit that is likely to contain voids.

According to an aspect of the present disclosure, a light-emitting apparatus includes:
a package substrate;
a light-emitting element mounted in a predetermined mounting region on an upper surface of the package substrate;
a light-transmitting member configured to cover an upper side of the mounting region on which the light-emitting element on the package substrate is mounted and transmit light emitted by the light-emitting element; and
a bonding layer configured to bond the upper surface of the package substrate in a periphery of the mounting region of the package substrate with a lower surface of the light-transmitting member and airtightly seal a space in a periphery of the light-emitting element. The bonding layer is made of glass. The bonding layer is disposed to surround the mounting region at a predetermined width. In a portion in which the bonding layer on the upper surface of the package substrate is disposed, a groove having a width narrower than the bonding layer is provided to surround the mounting region. The bonding layer includes a first bonding layer surrounding the mounting region on a side closer to the mounting region than the groove and a second bonding layer surrounding the mounting region on a side farther from the mounting region than the groove. A bottom surface of the groove is not in contact with the bonding layer.

According to another aspect of the present disclosure, a method of manufacturing a light-emitting apparatus includes:
a glass paste layer forming step of forming a glass paste layer with a frame shape having a predetermined width on a lower surface of a light-transmitting member that transmits light with a predetermined wavelength by a glass paste containing glass frit and a solvent;
a pre-baking step of pre-baking the glass paste layer printed on the light-transmitting member to remove the solvent and obtain an unmelted glass frit layer;
a package substrate preparing step of preparing a package substrate on which a light-emitting element is mounted in a mounting region on an upper surface of the package substrate and in which a groove having a frame shape corresponding to the frame shape of the glass frit layer in a periphery of the mounting region and having a width narrower than the glass frit layer is formed at a position corresponding to a center of the glass frit layer in a width direction;
a mounting step of mounting the light-transmitting member so that the glass frit layer overlaps the groove on the upper surface of the package substrate; and
a bonding layer forming step of heating and melting the glass frit layer to form a first bonding layer surrounding the mounting region on a side closer to the mounting region than the groove and a second bonding layer surrounding the mounting region on a side farther from the mounting region than the groove, bonding the upper surface of the package substrate with a lower surface of the light-transmitting member by the first bonding layer and the second bonding layer, and forming a space not in contact with the melted glass frit layer in the groove on a bottom surface of the groove.

According to the present invention, it is possible to provide a light-emitting apparatus in which a light-emitting element is sealed airtightly while using a glass material such as glass frit that is likely to contain voids.

### BRIEF DESCRIPTION OF THE DRAWINGS

FIG. 1A is a sectional view illustrating a light-emitting apparatus 1 according to the present invention, FIG. 1B is an expanded view of FIG. 1A, and FIGS. 1C and 1D are each a top view and a sectional view illustrating a package substrate of the light-emitting apparatus 1;

FIGS. 2A to 2E are diagrams illustrating a process of manufacturing the light-emitting apparatus 1 according to an embodiment;

FIGS. 3A and 3B are diagrams illustrating movement of voids inside a first bonding layer 26 and a second bonding layer 27 in a melted state in the process of manufacturing the light-emitting apparatus 1 according to the embodiment; and

FIG. 4A is a sectional view illustrating voids inside the first bonding layer 26 and the second bonding layer 27 of the light-emitting apparatus 1, and FIG. 4B is a sectional view illustrating voids inside a bonding layer of a light-emitting apparatus in which a groove 28 is not formed according to a comparative example.

### DESCRIPTION OF EMBODIMENTS

Hereinafter, an embodiment of the present invention will be described with reference to the drawings. The scope of the present invention is not limited to the embodiment to be described here and various modified examples can be made without departing from the gist of the present invention.

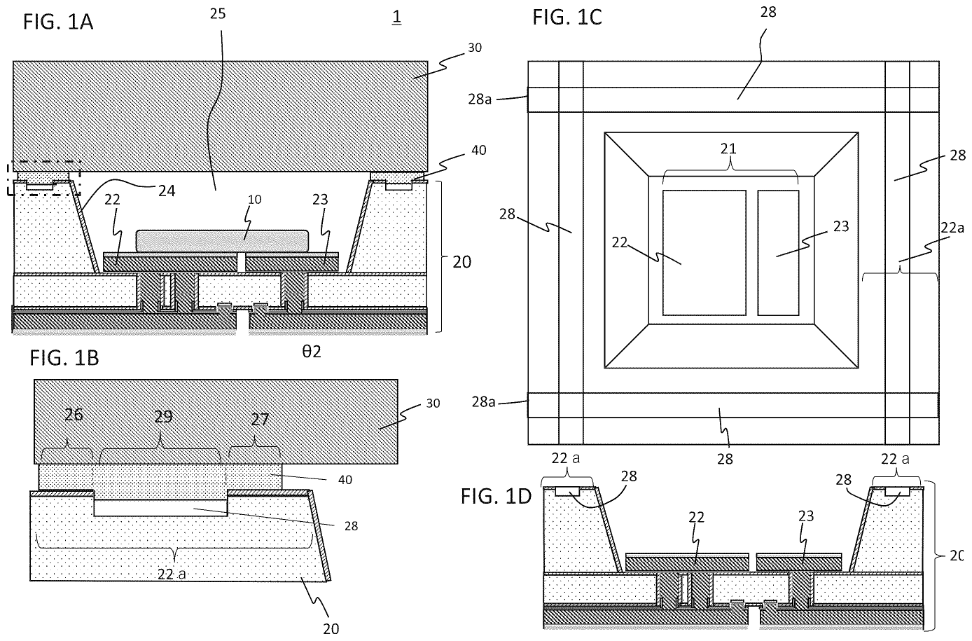

FIG. 1A is a sectional view illustrating a light-emitting apparatus 1 according to the present invention, and FIG. 1B is an expanded view of FIG. 1A. FIGS. 1C and 1D are each a top view and a sectional view illustrating a package substrate of the light-emitting apparatus 1.

As illustrated in FIG. 1A, the light-emitting apparatus 1 according to the invention includes a package substrate 20, a light-emitting element 10 mounted in a predetermined mounting region 21 on an upper surface of the package substrate 20, a light-transmitting member 30, and a bonding layer 40.

The light-emitting element 10 emits deep ultraviolet light (a wavelength of 100 to 280 nm).

In the package substrate 20, as illustrated in FIGS. 1A and 1C, a recess 25 is formed to dispose the light-emitting element 10. The mounting region 21 of the light-emitting element 10 is provided on a bottom surface of the recess. A pair of electrodes 22 and 23 are disposed in the mounting region 21. The light-emitting element 10 is mounted on the electrodes 22 and 23, and a pair of element electrodes (not illustrated) on a lower surface of the light-emitting element 10 are each bonded to the electrodes 22 and 23.

In the present embodiment, the package substrate 20 is made of Si and a surface of the package substrate 20 is covered with a thermal oxide film 24. The package substrate 20 may be made of another material without being limited to Si. For example, the package substrate 20 made of one of Si, low temperature co-fired ceramics (LTCC), Al₂O₃, and AlN or a composite material of two or more of such materials can be used.

The light-transmitting member 30 is made of a material that transmits light emitted by the light-emitting element 10. The light-transmitting member 30 covers a space of the recess 25 in which the light-emitting element 10 is disposed, and transmits light (deep ultraviolet light) emitted by the light-emitting element 10. As a material of the light-transmitting member 30, for example, any of borosilicate glass, synthetic quartz glass, and quartz glass can be used.

The recess 25 of the package substrate 20 may not be formed or may be formed in a flat-plate shape. When the flat-plate-shaped package substrate 20 is used, a structure may be used in which the light-emitting element 10 in the mounting region 21 is covered using the light-transmitting member 30 having a dome shape or the like.

A bonding layer 40 with a strip shape having a predetermined width is disposed on an upper surface of a periphery of the mounting region 21 on the package substrate 20 to surround the mounting region 21, and the upper surface of the package substrate 20 is bonded with a lower surface of the light-transmitting member 30. In the structure illustrated in FIGS. 1A to 1C, since the recess 25 is formed in the package substrate 20, a terrace (edge) 22a that is one stage higher than a bottom surface of the recess 25 is formed in the periphery of the mounting region 21. The bonding layer 40 airtightly bonds an upper surface of the terrace 22a of the package substrate 20 with the lower surface of the light-transmitting member 30. Accordingly, the bonding layer 40 airtightly seals a space in a periphery of the light-emitting element 10 against the outside.

The bonding layer 40 is made of glass. Specifically, the bonding layer 40 is formed by a plurality of glass particles (glass frit) fused together.

The glass that constitutes the bonding layer 40 is preferably a material that does not deteriorate due to the light emitted by the light-emitting element 10. Here, in the case of a configuration in which the light from the light-emitting element 10 is blocked by sidewalls of the recess 25 and cannot easily reach the bonding layer 40 as in FIG. 1A or the like, a material that deteriorates due to the light from the light-emitting element 10 can be used as a material that constitutes the bonding layer 40. Specifically, as the material that constitutes the bonding layer 40, for example, any of V₂O₅·ZnO, V₂O₅·TeO₂, Bi₂O₃·ZnO, borosilicate glass, synthetic quartz glass, and quartz glass can be used.

On the upper surface of the package substrate 20, as illustrated in FIG. 1C, a groove 28 having a width narrower than the bonding layer 40 is provided in a region in which the bonding layer 40 on the upper surface of the package substrate 20 is disposed. Accordingly, the bonding layer 40 includes a first bonding layer 26 surrounding the mounting region 21 on a side closer to the mounting region than the groove 28 and bonding the upper surface of the package substrate 20 with the lower surface of the light-transmitting member 30, and a second bonding layer 27 surrounding a mounting region on a side farther from the mounting region 21 than the groove 28 and bonding the upper surface of the package substrate 20 with the lower surface of the light-transmitting member 30.

The first bonding layer 26 serves to prevent leakage, achieve airtight sealing, and provide bonding strength. On the other hand, the second bonding layer 27 serves to increase a bonding area of the bonding layer 40 and enhance the bonding strength. For example, a width of the first bonding layer 26 can be set equal to a width of the second bonding layer 27.

On the bottom surface of the groove 28, there is a space not in contact with the bonding layer 40. Accordingly, in a portion in contact with at least the bottom surface of the space in the groove 28, a space that is not filled with the bonding layer 40 is formed. For high production yield, the bonding layer 40 is preferably produced to not be in contact with the entire bottom surface of the groove 28. However, as long as a space in which gas present between glass frit particles to be described below can move is provided in the groove 28, the bonding layer 40 may sag and come into contact with a part of the bottom surface of the groove 28 and a space in which the bonding layer 40 is not in contact with the remaining bottom surface may remain. Accordingly, it is possible to ensure a space in the groove 28 where gas can move. That is, as long as a space at which the bonding layer 40 is not in contact with the bottom surface is present in the groove 28, voids can be reduced.

To inhibit contact of the bonding layer 40 with the bottom surface of the groove 28, a depth of the groove 28 is preferably equal to or more than a thickness of the bonding layer 40.

For example, a film thickness of a frit glass paste layer for forming the bonding layer 40 is set to 2 to 15 μm because, when the film thickness of the frit glass paste layer is less than 2 μm, it is difficult to bond the package substrate 2 with the light-transmitting member 30 by the bonding layer 40, and when the film thickness is more than 15 μm, it is difficult to form a film by printing.

For example, the depth of the groove 28 is set to 10 to 200 μm because, when the depth of the groove 28 is less than 10 μm, it is difficult to form the groove 28, and when the depth of the groove 28 is more than 200 μm, strength of the package substrate 20 may deteriorate.

The width of the first bonding layer 26 is preferably set equal to or more than the width of the groove 28.

For example, the width of the groove 28 is set to be equal to or more than 10 μm and equal to or less than 100 μm because, when the width of the groove 28 is less than 10 μm, it is difficult to form the groove 28, and when the width of the groove 28 is less than 100 μm, the widths of the first bonding layer 26 and the second bonding layer 27 are narrowed and the bonding area is reduced, whereby it is difficult to achieve airtightness and maintain the bonding strength.

When voids contained in the first bonding layer 26 are continuous in the width direction of the first bonding layer 26 and connected with each other, leakage occurs. When the width of the first bonding layer 26 is too narrow, there is a high probability that a small number of voids are continuous in the width direction of the first bonding layer 26 and leakage occurs. When the width of the first bonding layer 26 is too narrow, the bonding area is narrowed and the bonding strength cannot be ensured. Accordingly, from the perspective of leakage prevention and the bonding strength, it is necessary to ensure a certain width of the first bonding layer 26. On the other hand, since the second bonding layer 27 is a layer serving to increase the bonding strength of the bonding layer 40, the bonding area of the second bonding layer 27 may be larger than that of the first bonding layer 26.

Since the width of the groove 28 is 10 to 100 μm and the depth of the groove 28 is 10 to 200 μm, as described above, a width-to-depth ratio is about 1 to 2. Regarding a relationship between the width of a surface of the terrace 22a bonded by the bonding layer 40 and the width of the groove 28, preferably, the width of the groove 28 is set as 100 μm when the width of the bonded surface is 150 μm, and set to 10 μm when the width of the bonded surface is 240 μm. Accordingly, a ratio of the width of the surface of the terrace 22a bonded by the bonding layer 40 to the width of the groove 28 is about 1.5 to 24.

In this way, the light-emitting apparatus 1 according to the present embodiment includes the groove 28 substantially at the center of the bonding layer 40 in the width direction. Thus, when the glass frit is melted to form the bonding layer 40, voids contained in the bonding layer 40 can be reduced. Accordingly, it is possible to inhibit a phenomenon in which a plurality of voids contained in the bonding layer 40 are connected in the width direction of the first bonding layer 26 and leakage occurs in airtight sealing of the first bonding layer 26. It is also possible to inhibit a phenomenon in which the bonding strength of the first bonding layer 26 and the second bonding layer 27 deteriorates. Accordingly, it is possible to achieve both of airtight sealing and bonding strength.

More specifically, when the bonding layer 40 is formed by a paste in which glass frit and binder are dispersed in a solvent, gas such as CO₂ contained in the paste remains as voids contained in the bonding layer 40 even after the glass frit is heated and melted and then cooled and solidified to form the bonding layer 40.

Conversely, in the structure of the light-emitting apparatus 1 according to the present embodiment, the groove 28 is provided at a position in contact with the bonding layer 40 in an unsolidified state. When the glass frit is melted, the gas present between the glass frit particles moves to the space in the groove 28 or moves to a non-bonding portion 29 located on the lower surface of the light-transmitting member 30 above the groove 28 by pressing the light-transmitting member 30 toward the package substrate 20. Accordingly, it is possible to reduce the voids contained in the first bonding layer 26 and the second bonding layer 27.

An end 28a of the groove 28 preferably has a structure extending across the second bonding layer 27 and reaching an end surface of the package substrate 20 to be opened on the end surface, as illustrated in FIG. 1C. Since the end 28a of the groove 28 is opened to the end surface of the package substrate 20, the space in the groove 28 communicates with a space in a periphery of the package substrate 20. Therefore, during formation of the bonding layer 40, when the glass frit is heated to several hundred degrees Celsius, a pressure difference occurs between a pressure of the end 28a of the groove 28 and a pressure of the space in the groove 28 in contact with the heated bonding layer 40 due to a temperature difference from the periphery. This pressure difference promotes movement of the gas between the glass frit particles to the space in the groove 28 or to the non-bonding portion 29 in the upper portion of the groove 28.

By providing the groove 28, when the glass frit is melted to form the bonding layer 40, the melted glass can be collected in the upper portion of the groove 28, as illustrated in FIG. 1B. Therefore, it is possible to inhibit the melted glass from overflowing toward the mounting region 21 or the edge of the package substrate 20 and causing a defect in the light-emitting apparatus 1.

The glass collected in the groove 28 as in FIG. 1B is cooled and solidified, then protrudes into the groove 28, and forms the non-bonding portion 29 in contact with a side surface of the groove 28. Since the non-bonding portion 29 protruding into the groove 28 has a shape engaged with the groove 28, an anchor effect can be produced to strengthen the bonding between the light-transmitting member 30 and the package substrate 20.

### Manufacturing Method

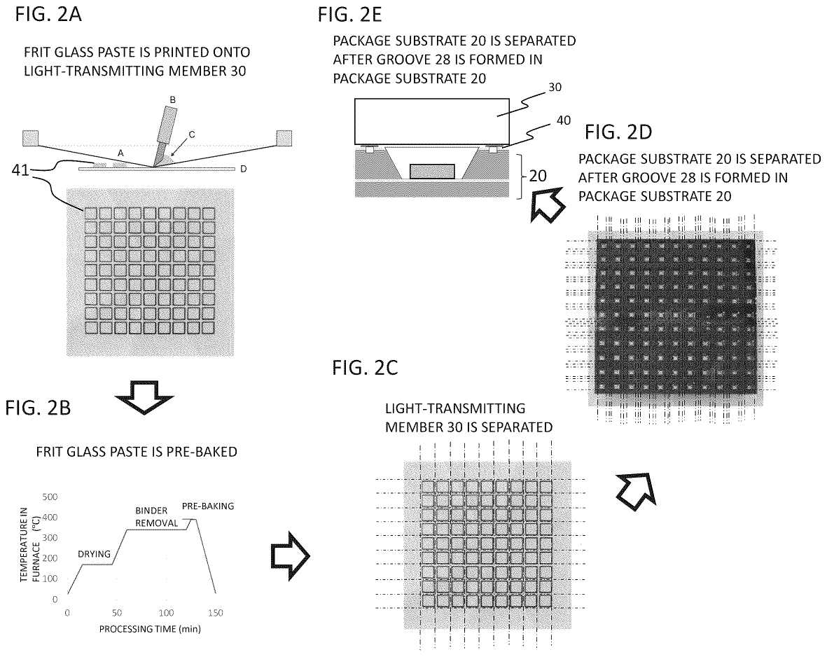

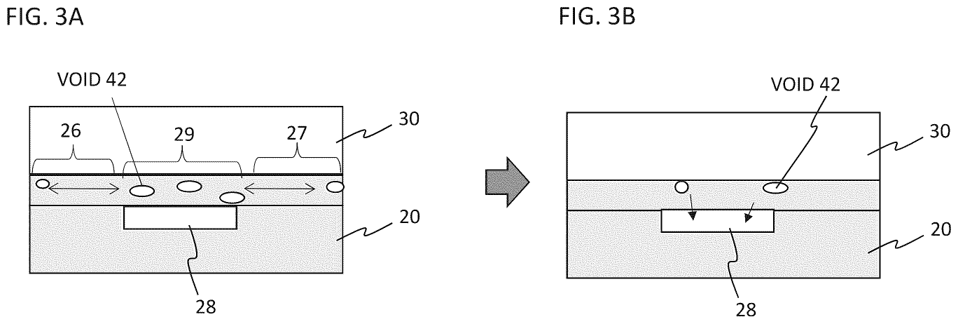

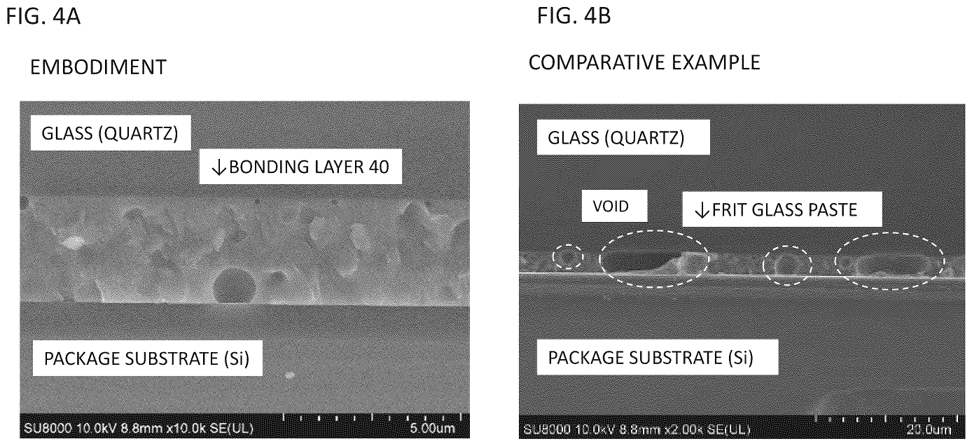

Hereinafter, a method of manufacturing the light-emitting apparatus according to the embodiment will be described with reference to FIGS. 2A to 4B. FIGS. 2A to 2E are diagrams illustrating a manufacturing process. FIGS. 3A and 3B are diagrams illustrating movement of voids, and FIGS. 4A and 4B are sectional views illustrating photos of the bonding layer 40 manufactured according to the embodiment and a comparative example.

### Step of Forming Frit Glass Paste Layer 41

As in FIG. 2A, first, the frit glass paste in which the glass frit and the binder are dispersed in the solvent is screen-printed onto the lower surface of the light-transmitting member 30 to form a frit glass paste layer 41 in a frame shape having a predetermined width. In the present step, the light-transmitting member 30 is in a state of a substrate in which the plurality of light-transmitting members 30 are connected.

When the depth of the groove 28 is, for example, 10 μm, the film thickness of the frit glass paste layer 41 is printed, for example, 2 μm that is thinner than the depth of the groove 28. Since the groove 28 and the bonding layer 40 are preferably not in contact with each other, it is necessary for the thickness of the frit glass paste layer 41 to be less than the depth of the groove 28.

A particle size of the frit glass contained in the frit glass paste is less than the film thickness of the frit glass paste layer 41 to be formed. For example, the frit glass that has an average particle diameter of about 0.1 to 10 μm or a particle size distribution D50 of about 0.1 to 10 μm is used.

As the solvent of the frit glass paste, for example, an organic solvent is used. As the binder, resin (for example, ethyl cellulose) can be used.

### Pre-Baking Step

As in FIG. 2B, the frit glass paste layer 41 printed onto the light-transmitting member is pre-baked, the solvent contained in the frit glass paste is removed, and the binder is baked and removed. Accordingly, an unmelted glass frit layer is formed.

The temperature of the pre-baking is a temperature at which the solvent can be evaporated and the binder can be baked, and is set to a temperature at which the glass frit is not melted. For example, as in FIG. 2B, heating is performed in order of 180° C. for 40 minutes, 350° C. for 60 minutes, and 400° C. for 10 minutes.

CO₂ generated during binder removal (solvent evaporation) in the pre-baking is mostly released to the outside of the frit glass paste layer 41 and partially remains.

### Step of Separating Light-Transmitting Member 30

As in FIG. 2C, the light-transmitting member 30 is separated by dicing into pieces of, for example, 2.55 mm.

### Step of Separating Package Substrate 20

On the other hand, a substrate is prepared in which a plurality of package substrates 20 on which the recesses 25 and the electrodes 22 and 23 are formed as in FIG. 2D are connected. After the groove 28 is formed in the terrace 22a in a periphery of the recess 25, separation is performed by dicing.

The light-emitting element 10 is bonded on the mounting region 21 in a bottom of the recess 25 of the separated package substrate 20.

### Step of Forming Bonding Layer

The light-transmitting member 30 is mounted on the groove 28 on the upper surface of the separated package substrate 20 so that the position of the center of the glass frit layer in the width direction overlaps.

The baking is performed by irradiating the glass frit layer with a laser from above the light-transmitting member 30 to heat the glass frit layer, or heating and melting the glass frit layer by hot press while pressing the light-transmitting member 30 toward the package substrate 20.

During the baking, the frit glass particles are melted. The gas remaining between the frit glass particles becomes voids contained in the melted glass. The melted glass serving as the first bonding layer 26 and the second bonding layer 27 in the bonding layer 40 is interposed between the light-transmitting member 30 and the package substrate 20, and thus a pressing force is applied thereto. Meanwhile, since the lower portion of the non-bonding portion 29 is the groove 28, no pressing force is applied to the melted glass therein. Accordingly, the voids in regions of the first bonding layer 26 and the second bonding layer 27 to which the pressing force is applied move into the region of the non-bonding portion 29 as in FIG. 3A. Further, air in the groove 28 expands during heating of the frit glass layer, is discharged to the atmosphere from the end 28a, and the interior of the groove 28 becomes negative in pressure. Accordingly, a difference occurs between a pressure of the space in the groove 28 and a pressure in the end 28a, and thus the voids in the non-bonding portion 29 are released to the space in the groove 28. Accordingly, as illustrated in FIG. 3B, the voids in the first bonding layer 26 and the second bonding layer 27 can be reduced.

As described above, the pressing force is applied to the melted glass in the region serving as the first bonding layer 26 and the second bonding layer 27, but the melted glass is collected in the upper portion of the groove 28 and does not overflow toward the mounting region 21 and the edge of the package substrate 20. Accordingly, a defect caused due to overflow of the melted glass can be reduced, and the glass collected in the upper portion of the groove 28 is in contact with the upper portion of the sidewalls of the groove 28 and thus acts on a wedge, whereby the light-transmitting member 30 is strongly bonded to the package substrate 20.

### Experiment Result of Leaving at Room Temperature

After the light-emitting apparatus 1 manufactured according to the above-described manufacturing method was left at the room temperature for three months, whether there is peeling of the bonding layer 40 was inspected visually. It was confirmed that no peeling occurred in the bonding layer 40.

### Industrial Applicability

The light-emitting apparatus 1 according to the present embodiment can be used for an apparatus that requires ultraviolet light, such as a sterilization light source (for example, a sterilizer for a slipper or the like in a metical institution), an air purifier, a water purifier, and the like.

The structure of the light-emitting apparatus 1 according to the present invention is not limited to the light-emitting apparatus 1 that emits ultraviolet light. The light-emitting apparatus 1 with any wavelength can be used as long as the apparatus is a light-emitting apparatus in which the light-emitting element 10 is airtightly sealed.

What is claimed is:

1. A light-emitting apparatus comprising:
a package substrate;
a light-emitting element mounted in a predetermined mounting region on an upper surface of the package substrate;
a light-transmitting member configured to cover an upper side of the mounting region on which the light-emitting element on the package substrate is mounted and transmit light emitted by the light-emitting element; and
a bonding layer configured to bond the upper surface of the package substrate in a periphery of the mounting region of the package substrate with a lower surface of the light-transmitting member and airtightly seal a space in a periphery of the light-emitting element, wherein
the bonding layer is made of glass,
the bonding layer is disposed to surround the mounting region at a predetermined width,
in a portion in which the bonding layer on the upper surface of the package substrate is disposed, a groove having a width narrower than the bonding layer is provided to surround the mounting region,
the bonding layer includes a first bonding layer surrounding the mounting region on a side closer to the mounting region than the groove and a second bonding layer surrounding the mounting region on a side farther from the mounting region than the groove, and
a space of a bottom surface of the groove is not in contact with the bonding layer.

2. The light-emitting apparatus according to claim 1, wherein the bonding layer is not in contact with the bottom surface of the groove.

3. The light-emitting apparatus according to claim 1, wherein in the groove, a space not filled with the bonding layer is formed in a portion that is in contact with at least the bottom surface of the groove.

4. The light-emitting apparatus according to claim 1, wherein a part of the groove extends across the second bonding layer and reaches an end surface of the package substrate.

5. The light-emitting apparatus according to claim 1, wherein glass that constitutes the bonding layer is formed by a plurality of glass particles fused together.

6. The light-emitting apparatus according to claim 1, wherein a width of the first bonding layer is equal to a width of the second bonding layer.

7. The light-emitting apparatus according to claim 1, wherein a depth of the groove is equal to or more than a thickness of the bonding layer.

8. The light-emitting apparatus according to claim 1, wherein a width of the first bonding layer is equal to or more than a width of the groove.

9. The light-emitting apparatus according to claim 8, wherein the width of the groove is equal to or more than 10 μm and equal to or less than 100 μm.

10. The light-emitting apparatus according to claim 1, wherein the light-emitting element emits deep ultraviolet light.

11. A method of manufacturing a light-emitting apparatus, the method comprising:
a glass paste layer forming step of forming a glass paste layer with a frame shape having a predetermined width on a lower surface of a light-transmitting member that transmits light with a predetermined wavelength by a glass paste containing glass frit and a solvent;
a pre-baking step of pre-baking the glass paste printed on the light-transmitting member to remove the solvent and obtain an unmelted glass frit layer;
a package substrate preparing step of preparing a package substrate on which a light-emitting element is mounted in a mounting region on an upper surface of the package substrate and in which a groove having a frame shape corresponding to the frame shape of the glass frit layer in a periphery of the mounting region and having a width narrower than the glass frit layer is formed at a position corresponding to a center of the glass frit layer in a width direction;
a mounting step of mounting the light-transmitting member so that the glass frit layer overlaps the groove on the upper surface of the package substrate; and
a bonding layer forming step of heating and melting the glass frit layer to form a first bonding layer surrounding the mounting region on a side closer to the mounting region than the groove and a second bonding layer surrounding the mounting region on a side farther from the mounting region than the groove, bonding the upper surface of the package substrate with a lower surface of the light-transmitting member by the first bonding layer and the second bonding layer, and forming a space not in contact with the melted glass frit layer in the groove on a bottom surface of the groove.

12. The method of manufacturing a light-emitting apparatus according to claim 11, wherein, in order for the melted glass frit layer not to come into contact with the bottom surface of the groove in the bonding layer forming step, a thickness of the glass paste layer to be formed is thinner than a depth of the groove in the glass paste layer forming step.
